(19) United States
(12) Patent Application Publication
(10) Pub. No.: US 2019/0096866 A1
(43) Pub. Date: Mar. 28, 2019

(54) SEMICONDUCTOR PACKAGE AND MANUFACTURING METHOD THEREOF

(71) Applicant: Powertech Technology Inc., Hsinchu County (TW)

(72) Inventors: Ching-Ming Hsu, Hsinchu County (TW); Wen-Hsiung Chang, Hsinchu County (TW); Po-Wei Yeh, Hsinchu County (TW); Yun-Hsin Yeh, Hsinchu County (TW)

(73) Assignee: Powertech Technology Inc., Hsinchu County (TW)

(21) Appl. No.: 15/715,169

(22) Filed: Sep. 26, 2017

(51) Int. Cl. H01L 25/18; H01L 21/768; H01L 23/48; H01L 23/31; H01L 25/00; H01L 23/00

(52) U.S. Cl. CPC H01L 25/18; H01L 21/561; H01L 21/76898; H01L 21/76846; H01L 23/481; H01L 23/3135; H01L 25/50; H01L 24/16; H01L 24/17; H01L 24/96; H01L 24/32; H01L 24/73; H01L 24/03; H01L 24/05; H01L 21/76871

(57) ABSTRACT

A semiconductor package including a first semiconductor chip, a plurality of first conductors, a first conductive pattern electrically connected to the first conductors, a second semiconductor chip disposed on the first semiconductor chip, and an encapsulant on the first conductive pattern and laterally encapsulating the second semiconductor chip. The first semiconductor chip electrically connected to the first conductors includes a sensing area on a first active surface, a first back surface and a plurality of through holes extending form the first back surface towards the first active surface. The second semiconductor chip including a second active surface facing towards the first back surface electrically connects the first semiconductor chip through the first conductors in the through holes and the first conductive pattern on the first back surface. A manufacturing method of a semiconductor package is also provided.

### BACKGROUND OF THE INVENTION

### 1. Field of the Invention

The present invention generally relates to a semiconductor package and a manufacturing method thereof, and more particularly, to a semiconductor package and a manufacturing method having a sensing area on a semiconductor chip.

### 2. Description of Related Art

In recent years, electronic apparatus, such as smart phones, tablet computers, wearable electronic device, and so forth, increasingly employ sensors to control the manipulation of a variety of functions provided by the device. Due to the increasing demands for high manufacturability and quality of the sensor packages, there are needs for flexibility and reliable methods for packaging the chips with sensors. Improving conventional methods of packaging the sensing chips is therefore desirable in order to achieve sensor packages with better operating performances and greater manufacturability.

### SUMMARY OF THE INVENTION

The disclosure provides a semiconductor package and a manufacturing method thereof, which achieves optimal wafer level integration and interconnect form semiconductor chips having sensors.

The disclosure provides a semiconductor package including a first semiconductor chip, a plurality of first conductors, a first conductive pattern, a second semiconductor chip, a plurality of conductive features and an encapsulant. The first semiconductor chip includes a first active surface, a sensing area on the first active surface, a first back surface opposite to the first active surface and a plurality of through holes extending form the first back surface towards the first active surface. The first conductors are disposed in the through holes of the first semiconductor chip and electrically connected to the first semiconductor chip. The first conductive pattern is disposed on the first back surface of the first semiconductor chip and electrically connected to the first conductors. The second semiconductor chip is disposed on the first conductive pattern and includes a second active surface facing towards the first back surface of the first semiconductor chip. The second semiconductor chip is electrically connected to the first semiconductor chip. The encapsulant is disposed on the first conductive pattern and laterally encapsulates the second semiconductor chip.

The disclosure provides a manufacturing method of a semiconductor package. The method includes at least the following steps. A first semiconductor chip is provided. The first semiconductor chip includes a first active surface, a sensing area on the first active surface, a first back surface opposite to the first active surface and a plurality of through holes extending form the first back surface towards the first active surface. A plurality of first conductors is formed in the through holes of the first semiconductor chip. A first conductive pattern is formed on the first back surface of the first semiconductor chip to electrically connect the first conductors. A second semiconductor chip is disposed on the first conductive pattern. The second semiconductor chip includes a second active surface facing towards the first back surface of the first semiconductor chip, and the second semiconductor chip is electrically connected to the first semiconductor chip through the first conductive pattern. An encapsulant is formed on the first conductive pattern to laterally encapsulate the second semiconductor chip.

Based on the above, the second active surface of the second semiconductor chip faces towards the first back surface of the first semiconductor chip. In addition, the first semiconductor chip and the second semiconductor chip are electrically connected to each other through the first conductors and the first conductive pattern formed between the first semiconductor chip and the second semiconductor chip. As such, the semiconductor package provides a short electrical conduction path from the first semiconductor chip to the second semiconductor chip in order to reduce signal propagation, lower capacitance, and achieve better circuit performance. Furthermore, the first semiconductor chip has the sensing area facing towards the external environment and the distance between the top surface of the semiconductor package and the sensing area of the first semiconductor chip is reduced to achieve an improved sensing capability of the semiconductor package.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1J are schematic cross-sectional views illustrating a manufacturing method of a semiconductor package according to an embodiment of the disclosure.

FIG. 2A and FIG. 2B are schematic cross-sectional views illustrating a manufacturing method of the enlarged TV area the semiconductor package in FIG. 1C.

FIG. 3A to FIG. 3D are schematic cross-sectional views illustrating a manufacturing method of a semiconductor package according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

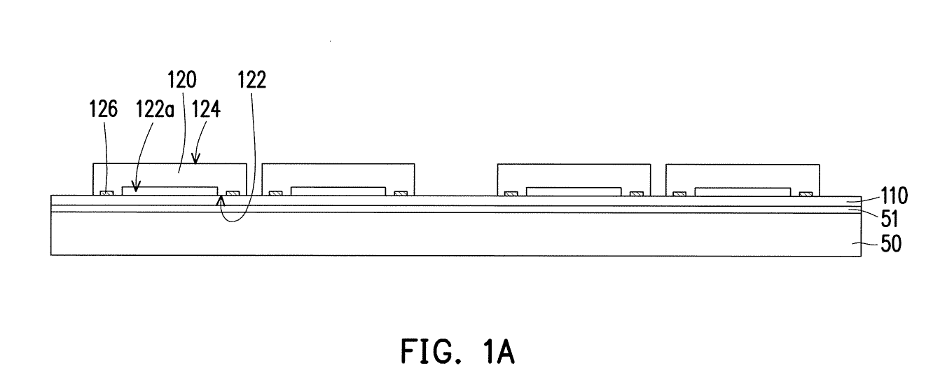

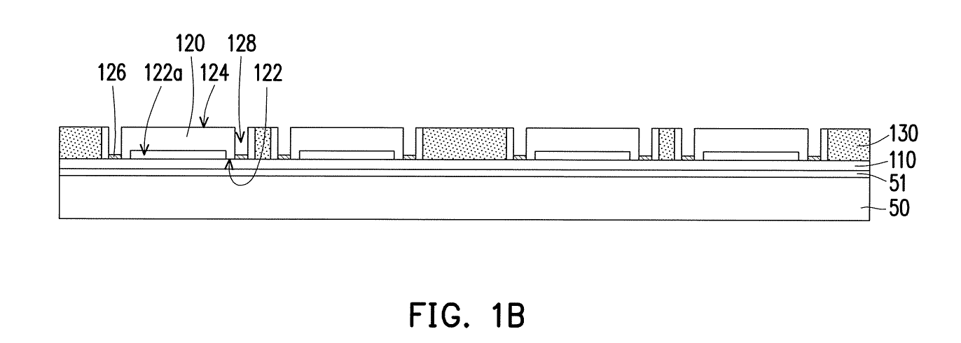

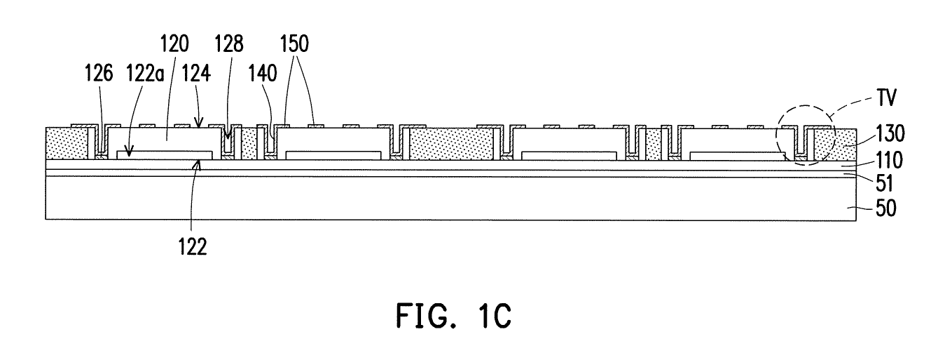

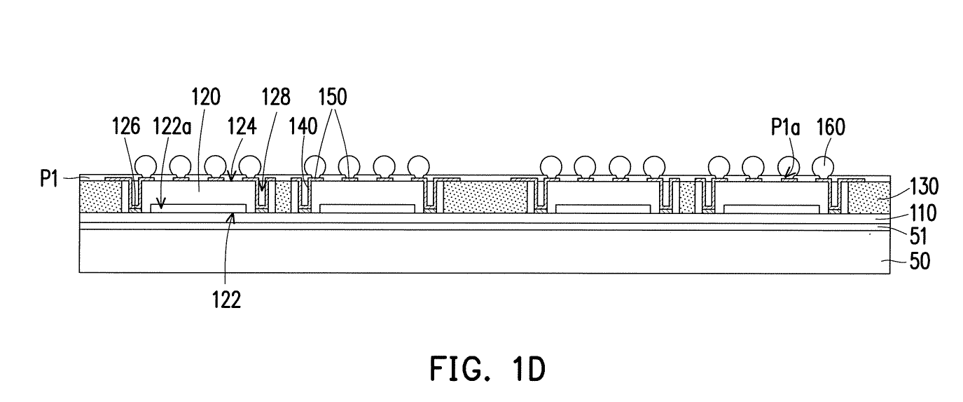

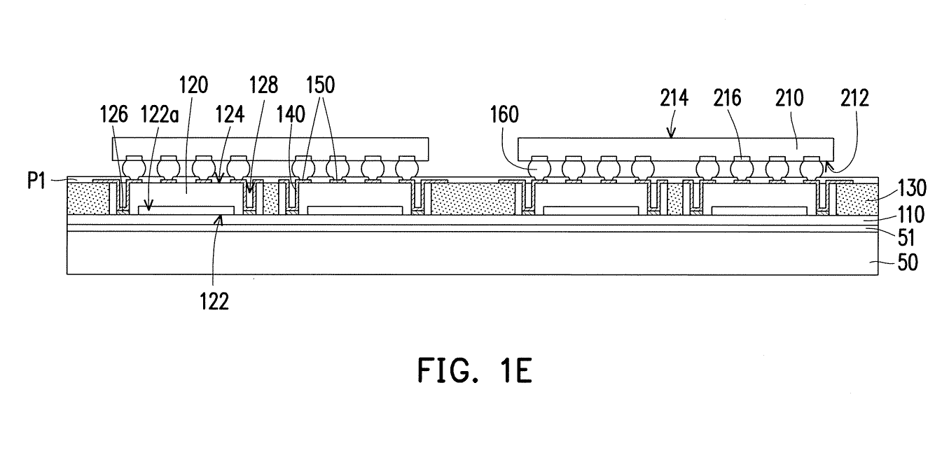

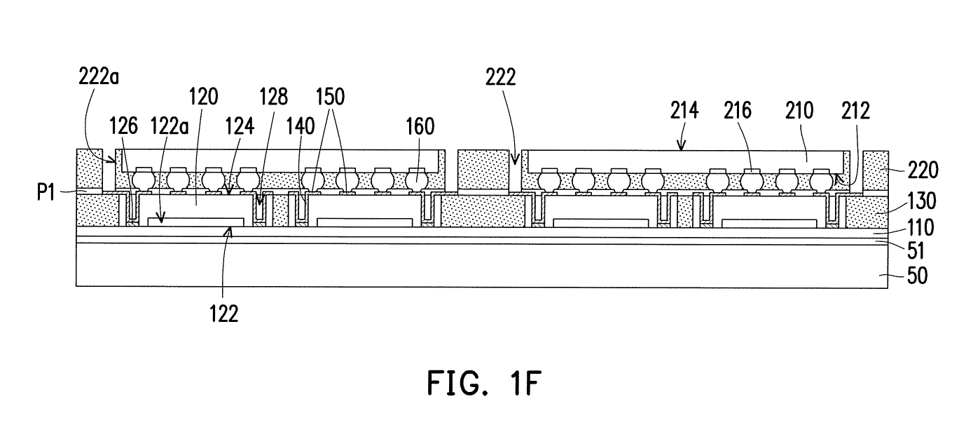

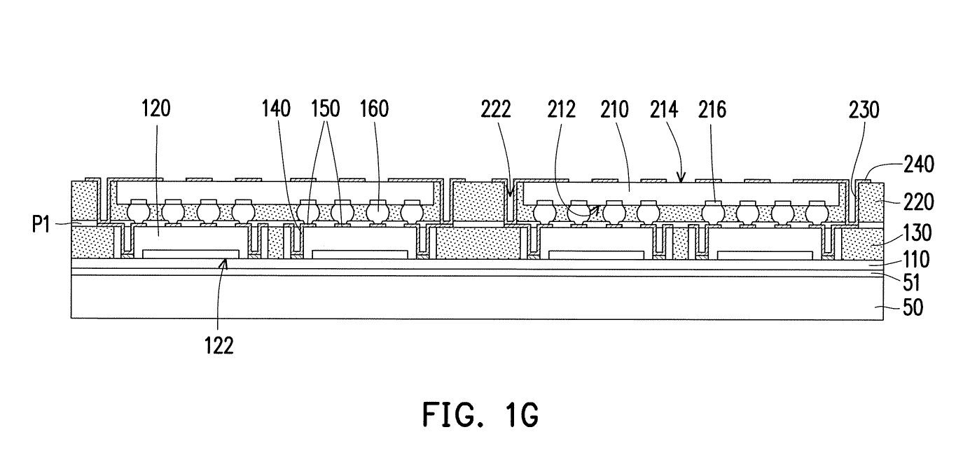

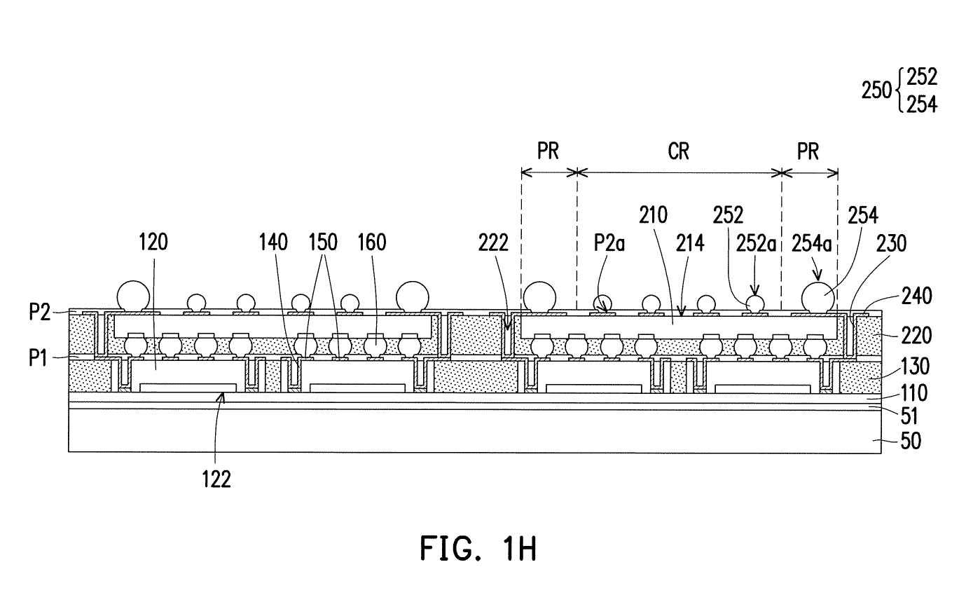

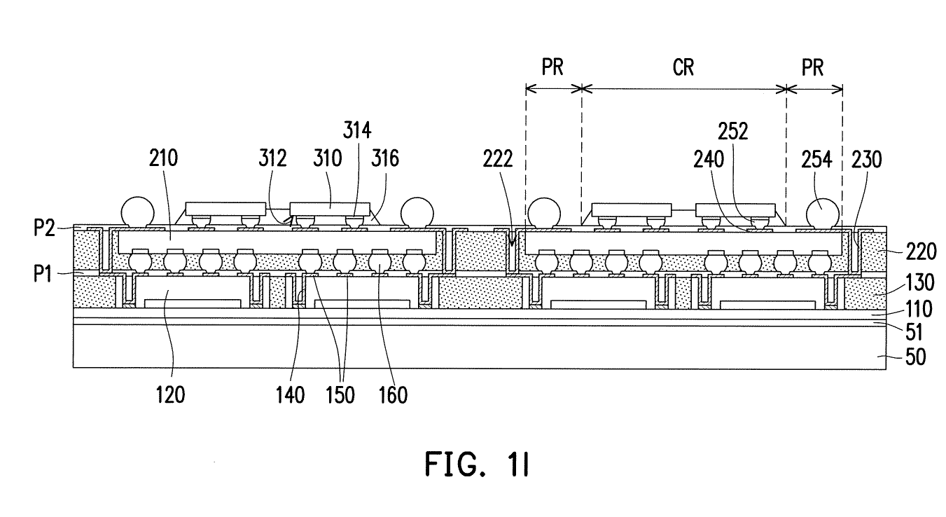

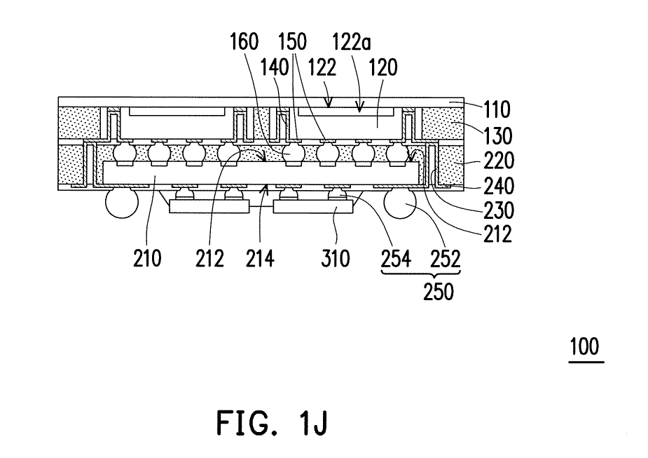

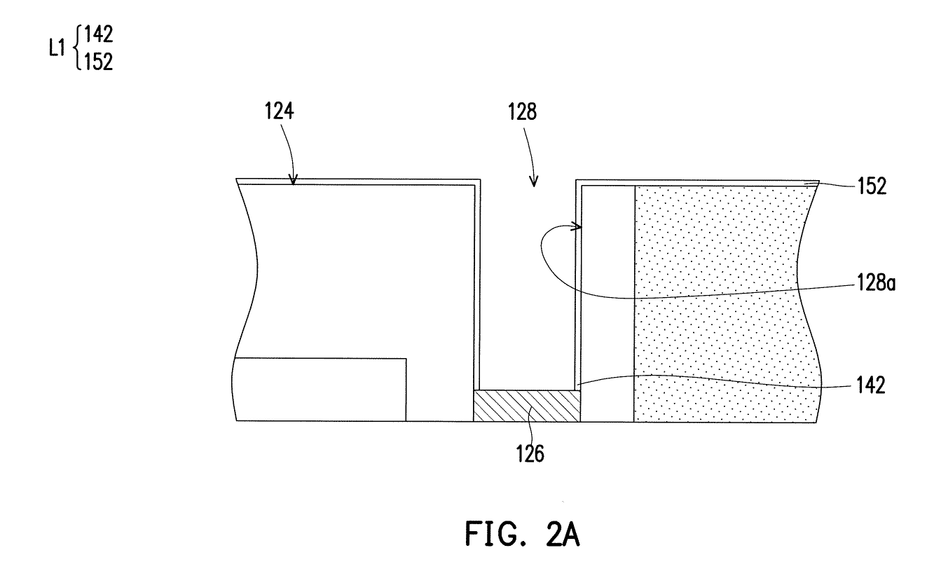

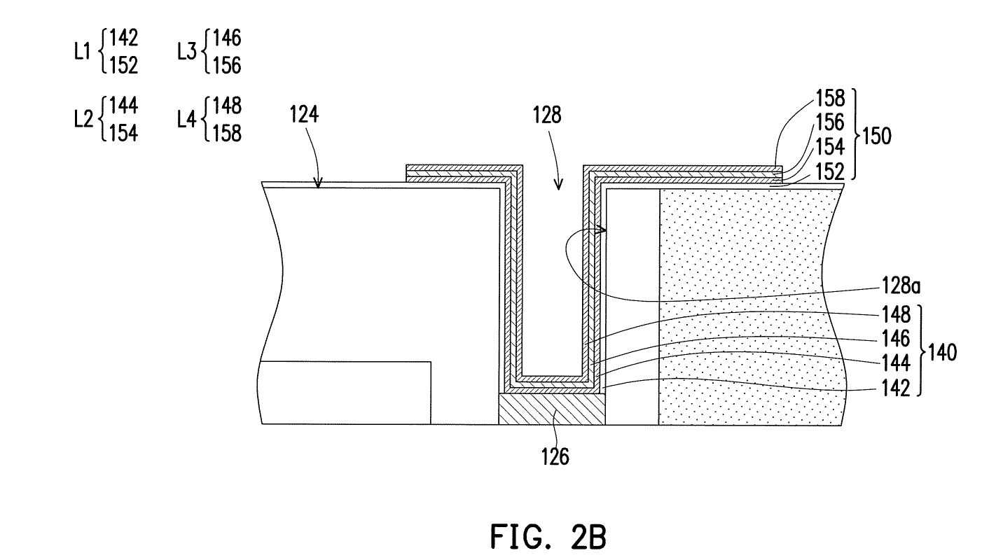

FIG. 1A to FIG. 1J are schematic cross-sectional views illustrating a manufacturing method of a semiconductor package according to an embodiment of the disclosure and FIG. 2A and FIG. 2B are schematic cross-sectional views illustrating a manufacturing method of the enlarged TV area the semiconductor package in FIG. 1C. Referring to FIG. 1A, a temporary carrier 50 may be provided. The temporary carrier 50 may be a glass substrate, a wafer substrate, or other suitable substrate material as long as the material is able to withstand the subsequent processes while carrying the package formed thereon. In some embodiments, a de-bonding layer 51 may be formed on the temporary carrier 50 to enhance the releasability of the package from the temporary carrier 50 in the subsequent processes. For example, the de-bonding layer 51 may be a light to heat conversion (LTHC) release layer or other suitable release layers. A cover layer 110 may be formed on the de-bonding layer 51. In some embodiments, without the de-bonding layer 51, the cover layer 110 may be formed directly on the temporary carrier 50. For example, the cover layer 110 may be a hard coating layer formed from polymer, curable resin, or other suitable protective materials using a deposition process, a spin coating process, a slit coating process or other suitable processes.

Subsequently, a first semiconductor chip 120 may be disposed on the cover layer 110. In some embodiments, after disposing the first semiconductor chip 120, a curing process may be performed on the cover layer 110 to enhance protection of the first semiconductor chip 120 depending on the design requirements. For example, the first semiconductor chip 120 may include a first active surface 122, a sensing area 122a on the first active surface 122, and a first back surface 124 opposite to the first active surface 122. In some other embodiments, the first semiconductor chip 120 may include a plurality of first conductive pads 126 on the first active surface 122 surrounding the sensing area 122a. For example, the first semiconductor chip 120 may be disposed on the cover layer 110 with the first active surface 122 facing towards the cover layer 110. In other words, the sensing area 122a and the first conductive pads 126 on the first active surface 122 of the first semiconductor chip 120 may be covered by the cover layer 110.

In some embodiments, more than one first semiconductor chips 120 may be disposed on the cover layer 110. The amount of the first semiconductor chips 120 in FIG. 1A merely serves as an exemplary illustration and the disclosure is not limited thereto. For example, the first semiconductor chip 120 may include optical sensors which may employ photodetectors such as photodiodes, phototransistors, or the like, to sense light and convert the received light energy into electrical signals for processing by the electronic circuitry on the first semiconductor chip 120. In some embodiments, multiple first semiconductor chips 120 may individually collect distinct wavelengths of light and provide complementary spectral responsivity. In such cases, the cover layer 110 may be translucent or transparent to pass light to the sensing area 122a of the first semiconductor chips 120. Other suitable sensors may be applied to the first semiconductor chips 120 depending on design requirements, which is not limited thereto.

Referring to FIG. 1B, an encapsulating layer 130 may be formed on the temporary carrier 50 to laterally encapsulate the first semiconductor chips 120. The encapsulating layer 130 may include a molding compound formed by a molding process (e.g., over-molding process). In some embodiments, the encapsulating layer 130 may be formed by an insulating material such as epoxy or other suitable resins. In some other embodiments, a thickness of the encapsulating layer 130 may be greater than the thickness of the first semiconductor chips 120. In such case, the thickness of the encapsulating layer 130 may be reduced to expose the first back surfaces 124 of the first semiconductor chips 120 using, for example, a grinding process or other suitable process. In some other embodiments, a portion of the bulk semiconductor material on the first back surfaces 124 of the first semiconductor chips 120 may be removed during the thickness reducing process. The first back surface 124 may be coplanar with the top surface of the encapsulating layer 130 facing away to the temporary carrier 50. After forming the encapsulating layer 130, a plurality of through holes 128 may be formed from the first back surface 124 towards the first active surface 122 on each of the first semiconductor chips 120 using etching, drilling, or other suitable process to expose the first conductive pads 126 for further electrical connection.

Referring to FIG. 1C, FIG. 2A and FIG. 2B, a plurality of first conductors 140 may be formed in the through holes 128 of each of the first semiconductor chips 120 to electrically connect to the first conductive pads 126. A first conductive pattern 150 electrically connected to the first conductors 140 may be formed on the first back surfaces 124 of the first semiconductor chips 120. In some embodiments, a portion of the first conductive pattern 150 may be formed on the top surface of the encapsulating layer 130 facing away to the temporary carrier 50 for further electrical connection. Since the first conductive pattern 150 can redistribute the conductive trace for signal transmitting of the first semiconductor chips 120, the first conductive pattern 150 may be referred to a redistribution layer. In some embodiments, the first conductors 140 and the first conductive pattern 150 may be formed simultaneously during the same process.

Referring to FIG. 2A, an insulating material may be formed in the through holes 128 and on the first back surfaces 124 of the first semiconductor chips 120 using, for example, a deposition process, a spin coating process, or other suitable process. The insulating material may be made of polymer, such as polyimide, polybenzoxazole (PBO), benzocyclobutene (BCB), or made of silicon oxide, such as tetraethoxysilane (TEOS) Chemical Vapor Deposition (CVD) silicon oxide, Atomic layer deposition (ALD) silicon oxide, or the like. Subsequently, a bottom portion of the insulating material inside the through holes 128 may be removed to expose the first conductive pads 126 using, for example, etching process to form an insulating layer L1. For example, the insulating layer L1 may include a first portion 142 formed on the inner sidewall 128a of the through holes 128 and a second portion 152 formed on the first back surface 124 and coupled to the first portion 142.

Referring to FIG. 2B, after the insulating layer L1 is formed, a barrier layer L2, a seed layer L3 and a conductive layer L4 may be formed and patterned sequentially in the through holes 128 and on the first back surface 124 of the first semiconductor chip 120 to cover the insulating layer L1 and the first conductive pads 126. In some embodiments, after forming the barrier layer L2, at least a portion of the insulating layer L1 on the first back surface 124 of the first semiconductor chip 120 may be exposed by the barrier layer L2. In some other embodiments, the seed layer L3 may be conformally formed on the barrier layer L2 and the conductive layer L4 may be conformally formed on the seed layer L3. The barrier layer L2 serving as a diffusion barrier may prevent migration of conductive layers formed thereon into dielectric. The seed layer L3 may improve the adhesion of the conductive layer L4 into the through holes 128. In some alternative embodiments, the conductive layer L4 may be plated as pillars filling the through holes 128. A material of the barrier layer L2 may include titanium, tantalum, or other suitable materials. A material of the seed layer L3 may include copper, gold, nickel, or an alloy thereof. A material of the conductive layer L4 may include copper, gold, silver, or a combination thereof.

For example, the barrier layer L2 may include a first portion 144 formed in the through holes 128 and coupled to the first conductive pads 126 and a second portion 154 formed on the first back surface 124 and coupled to the first portion 144. The seed layer L3 covering the barrier layer L2 may include a first portion 146 formed in the through holes 128 and a second portion 156 formed on the first back surface 124 and coupled to the first portion 146. The conductive layer L4 covering the seed layer L3 may include a first portion 148 formed in the through holes 128 and a second portion 158 formed on the first back surface 124 and coupled to the first portion 148. The portions formed in the through holes 128 (e.g. the first portion 142 of the insulating layer L1, the first portion 144 of the barrier layer L2, the first portion 146 of the seed layer L3 and the first portion 148 of the conductive layer L4) may be referred to as the first conductors 140. In some embodiments, the first conductors 140 in the through holes 128 may be referred to through silicon vias (TSVs). The portions formed on the first back surface 124 (e.g. the second portion 152 of the insulating layer L1, the second portion 154 of the barrier layer L2, the second portion 156 of the seed layer L3, and the second portion 158 of the conductive layer L4) may referred to the first conductive pattern 150. The first conductors 140 extending through the first semiconductor chip 120 and electrically connected to the first conductive pattern 150 may provide I/O contact with the first conductive pads 126 at the back surface 124 of the first semiconductor chip 120.

Referring to FIG. 1D, a plurality of conductive features 160 may be formed on the first conductive pattern 150 using, for example, a plating process, a ball placement process or other suitable process. In some embodiments, a first passivation layer P1 having a plurality of openings P1a may be formed on the first conductive pattern 150 and/or the encapsulating layer 130. For example, a passivation material (e.g. epoxy, polyimide, polybenzoxazole (PBO), benzocyclobutene (BCB)) may be formed over the first conductive pattern 150 and the encapsulating layer 130. Next, a portion of the passivation material may be removed to form the first passivation layer P1 with openings P1a to expose at least a portion of the first conductive pattern 150. In some embodiments, the first passivation layer P1 may include a photoresist material and the openings P1a may be formed by exposure and developing processes. Subsequently, the conductive features 160 may be formed in the openings P1a of the first passivation layer P1 to directly contact the exposed first conductive pattern 150 and electrically connect the first semiconductor chips 120. In some embodiments, the conductive features 160 may include conductive balls, conductive pillars, conductive bumps or a combination thereof. However, it construes no limitation in the disclosure. Other possible forms and shapes of the conductive features 160 may be utilized according to the design requirement. A soldering process and a reflowing process are optionally performed for enhancement of the adhesion between the conductive features 160 and the first conductive pattern 150.

Referring to FIG. 1E, a second semiconductor chip 210 may be disposed on the first conductive pattern 150 through the conductive features 160. For example, the second semiconductor chip 210 may include a second active surface 212 facing towards the first back surfaces 124 of the first semiconductor chips 120, a second back surface 214 opposite to the second active surface 212, and a plurality of second conductive pads 216 distributed on the second active surface 212. In other words, the second active surface 212 of the second semiconductor chip 210 and the first active surface 122 of the first semiconductor chip 120 may face towards each other. The second semiconductor chip 210 may be electrically connected to the first semiconductor chips 120 through the first conductive pattern 150. In other words, the electrical signals going through the first semiconductor chips 120 can be routed through the first conductive pads 126 to the first conductors 140, the first conductive pattern 150, the conductive features 160, and to the second conductive pads 216 of the second semiconductor chip 210.

Referring to FIG. 1F, an encapsulant 220 is formed on the first conductive pattern 150 to laterally encapsulate the second semiconductor chip 210 and the conductive features 160. In other words, the second semiconductor 210 encapsulated by the encapsulant 220 may be disposed on the first semiconductor chips 120 and the encapsulating layer 130. The encapsulant 220 may be similar with the encapsulating layer 130. For example, the encapsulant 220 may include a molding compound formed by a molding process (e.g., over-molding process). In some other embodiments, a thickness of the encapsulant 220 may be greater than the thickness of the second semiconductor chip 210. In such case, the thickness of the encapsulant 220 may be reduced to expose the second back surfaces 214 of the second semiconductor chip 210 using, for example, a grinding process or other suitable process. In some other embodiments, a portion of the bulk semiconductor material on the second back surface 214 of the second semiconductor chip 210 may be removed during the thickness reducing process. The second back surface 214 may be coplanar with the top surface of the encapsulant 220. The top surface of the encapsulant 220 is a surface facing away to the encapsulating layer 130. In some embodiments, after forming the encapsulant 220, a plurality of through holes 222 may be formed on the encapsulant 220 surrounding the second semiconductor chip 210 using, for example, a laser drilling process, a mechanical drilling process or other suitable process. The through holes 222 may expose at least a portion of the first conductive pattern 150 for further electrical connection.

Referring to FIG. 1G, a plurality of second conductors 230 may be formed in the through holes 222 to be electrically connected to the first conductive pattern 150 and the first semiconductor chips 120. A second conductive pattern 240 electrically connected to the second conductors 230 may be formed on the second back surface 214 of the second semiconductor chip 210. Since the second conductive pattern 240 can redistribute the conductive trace for signal transmitting of the second semiconductor chip 210, the second conductive pattern 240 may be referred to a redistribution layer, similar with the first conductive pattern 150. In some embodiments, the second conductors 230 and the second conductive pattern 240 may be formed simultaneously during the same process. For example, a conductive material (not shown), such as copper, aluminium, nickel, or the like, may be formed over the second back surface 214 of the second semiconductor chip 210 and in the through holes 222 of the encapsulant 220 through a sputtering process, a deposition process, or an electroplating process, or other suitable process. Next, the conductive material may be patterned by a photolithography and etching process to form the patterned conductive layer. A portion of the patterned conductive layer formed in the through holes 222 may be referred to the second conductors 230 and another portion of the patterned conductive layer formed on the second back surface 214 of the second semiconductor chip 210 may be referred to the second conductive pattern 240. In some embodiments, a seed material may be formed over the second back surface 214 of the second semiconductor chip 210 and in the through holes 222 of the encapsulant 220 before the conductive material.

Referring to FIG. 1H, a plurality of conductive terminals 250 may be formed on the second conductive pattern 240 to be electrically connected to the first semiconductor chips 120 and the second semiconductor chip 210. In some embodiments, a second passivation layer P2 having a plurality of openings P2a may be formed on the encapsulant 220 to cover the second conductive pattern 240 and at least a portion of the second conductive pattern 240 may be exposed by the openings P2a of the second passivation layer P2. The forming process of the second passivation layer P2 may be similar with the first passivation layer P1 and the detailed descriptions are omitted. Subsequently, the conductive terminals 250 may be formed in the openings P2a of the second passivation layer P2 to directly contact the exposed second conductive pattern 240 and electrically connect to the second semiconductor chip 210. The conductive terminals 250 may include conductive balls, conductive pillars, conductive bumps, or a combination thereof formed by, for example, a ball placement process, a plating process, or other suitable process. However, it construes no limitation in the disclosure. Moreover, a soldering process and a reflowing process are optionally performed for enhancement of the adhesion between the conductive terminals 250 and the second conductive pattern 240.

In some embodiments, the conductive terminals 250 may include a plurality of first elements 252 formed in a central region CR of the second semiconductor chip 210 and a plurality of second elements 254 formed in a peripheral region PR of the second semiconductor chip 210 surrounding the central region CR. The size of the second elements 254 may be larger than the size of the first elements 252. In other words, the shortest distance from the top surfaces 252a of the first elements 252 to the second conductive pattern 240 may be less than the shortest distance from the top surfaces 254a of the second elements 254 to the second conductive pattern 240. In some alternative embodiments, the top surfaces 252a of the first elements 252 may be aligned with the top surfaces 254a of the second elements 254.

Referring to FIG. 1I, a third semiconductor chip 310 may be disposed on the second conductive pattern 240. For example, the third semiconductor chip 310 may include a front surface 312 facing towards the second back surface 214 of the second semiconductor chip 210 and a plurality of conductive connectors 314 distributed on the front surface 312. The conductive connectors 314 of the third semiconductor chip 310 may be electrically connected to the second conductive pattern 240. In some embodiments, the third semiconductor chip 310 may be disposed on the second conductive pattern 240 before forming the conductive terminals 250. In such case, after the third semiconductor chip 310 is disposed on the second conductive pattern 240 using flip-chip technique, forming the first elements 252 of the conductive terminals 250 may be omitted. In other words, the third semiconductor chip 310 may be electrically connected to the second conductive pattern 240 directly through the conductive connectors 314 which may serve as the first elements 252 such that forming the first elements 252 of the conductive terminals 250 may be unnecessary. In some other embodiments, an underfill 316 may be formed in the gap between the third semiconductor chip 310 and the second passivation layer P2 to enhance the reliability of the attachment process. In an exemplary embodiments, the third semiconductor chip 310 serving as a memory is electrically connected to the first semiconductor chip 120 having the sensing area 122a and the second semiconductor chip 210 which serves as a processor. In such cases, the third semiconductor chip 310 may be executed by the second semiconductor chip 210 to perform various applications. In some other embodiments, more than one third semiconductor chips 310 serving different functions may be disposed on the second conductive pattern 240. The amount of the third semiconductor chips 310 in FIG. 1I merely serves as an exemplary illustration and the disclosure is not limited thereto.

A singulation process may be performed and the temporary carrier 50 may be removed such that the manufacturing process of a semiconductor package 100 is substantially completed as shown in FIG. 1J. For example, after disposing the third semiconductor chips 310, the singulation process may be performed. Subsequently, the temporary carrier 50 may be removed from the cover layer 110. For example, the external energy such as UV laser, visible light or heat, may be applied to the de-bonding layer 51 so that the cover layer 110 may be peeled off from the temporary carrier 50. In some embodiments, the singulation process may be performed before disposing the third semiconductor chip 310. The process sequence of the singulation and disposing the third semiconductor chip 310 construes no limitation in the disclosure. The aforementioned manufacturing method of the semiconductor package 100 integrating the first semiconductor chip 120, the second semiconductor chip 210 and the third semiconductor chip 310 may achieve better operating performances and greater manufacturability.

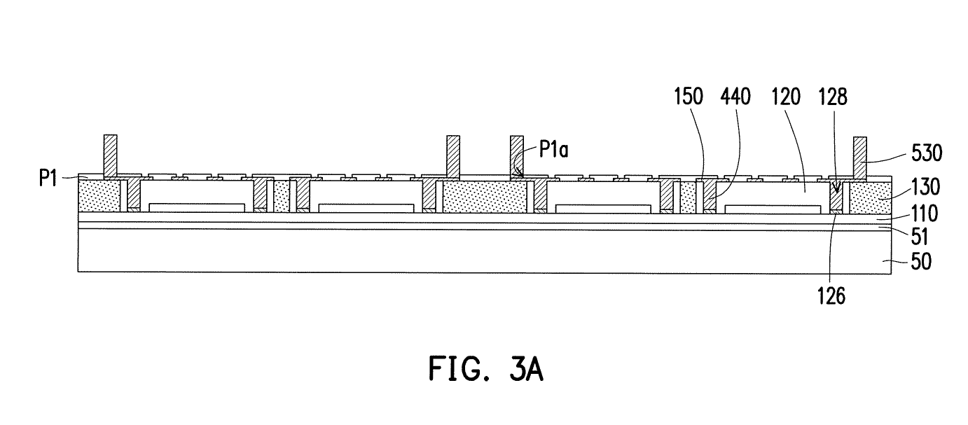

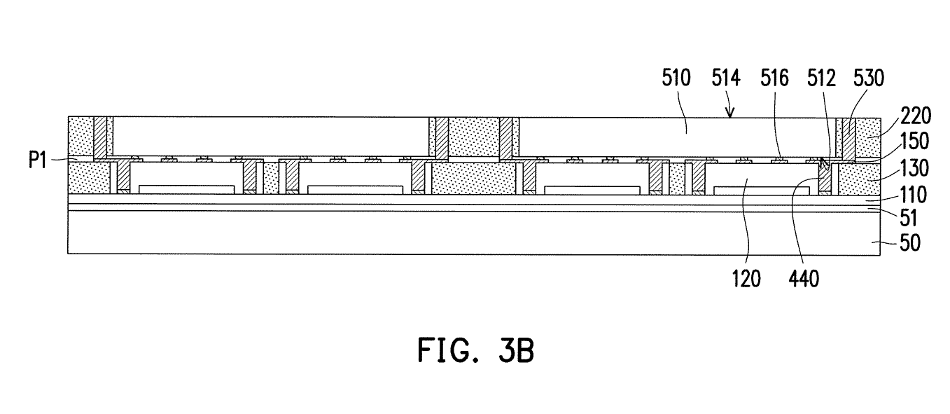

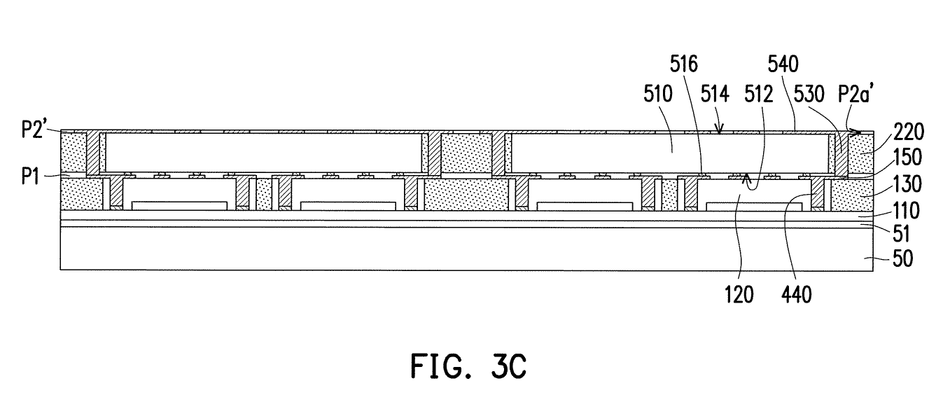

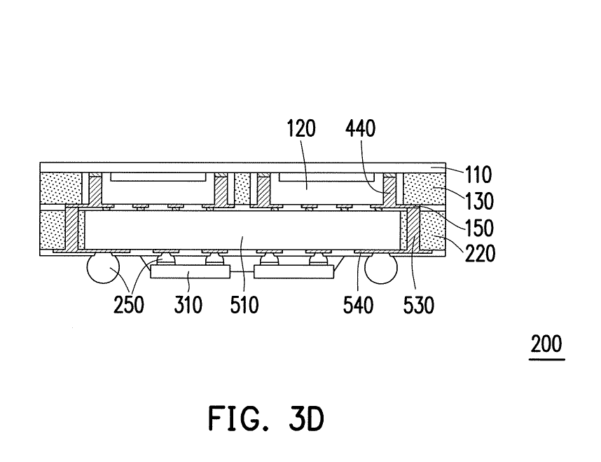

FIG. 3A to FIG. 3D are schematic cross-sectional views illustrating a manufacturing method of a semiconductor package according to an embodiment of the disclosure. The manufacturing method of the present embodiment is similar to the embodiment illustrated in FIG. 1A to FIG. 1J and the process descriptions may be omitted for brevity. Referring to FIG. 3A, the first conductors 440 may be formed as pillars filling the through holes 128 of the first semiconductor chip 120 and electrically connected to the first conductive pattern 150. For example, the topmost conductive layer L4 as shown in FIG. 2B may be formed to fill the through holes 128 after the insulating layer L1, the barrier layer L2 and the seed layer L3 are formed. Next, after forming the first conductive pattern 150 and the first conductors 440, the first passivation layer P1 may be formed on the first conductive pattern 150 and the encapsulating layer 130. The first passivation layer P1 having the openings P1a exposes at least a portion of the first conductive pattern 150. Subsequently, a plurality of the second conductors 530 may be formed on the exposed first conductive pattern 150.

For example, a patterned photoresist layer (not shown) having a predetermined pattern may be formed over the first passivation layer P1 by such as spin coating of a photoresist material layer, baking of the photoresist material layer, and photolithography (i.e. exposure and development processes). Portions of the exposed first conductive pattern 150 may be further exposed by the patterned photoresist layer. Next, the second conductors 530 may be formed by such as a plating process or other suitable process on the exposed first conductive pattern 150 which is also revealed by the patterned photoresist layer. After the second conductors 530 are formed, the patterned photoresist layer may be stripped by, for example, etching, ash or other suitable removal processes.

Referring to FIG. 3B, after forming the second conductors 530, the second semiconductor chip 510 may be disposed on the first conductive pattern 150 through flip-chip bonding. In other words, in the present embodiment, a flip-chip technique is employed and the first semiconductor chips 120 and the second semiconductor chip 510 are electrically connected through the second conductive pads 516 distributed on the second active surface 512. Compared with the embodiment illustrated in FIG. 1E, in the present embodiment, the conductive features formed between the first semiconductor chips 120 and the second semiconductor chip 510 may be omitted. In some embodiments, the second conductors 530 may be formed surrounding the first semiconductor chips 120 and the second semiconductor chip 210 may be disposed on the first conductive pattern 150 with the first semiconductor chips 150 overlying the second semiconductor chip 510. Subsequently, the encapsulant 220 may be formed to laterally encapsulate the second semiconductor chip 510 and the second conductors 530. The forming process of the encapsulant 220 may be similar with the embodiments illustrated in FIG. 1F and the detailed descriptions are omitted. The thickness of the encapsulant 220 may be reduced to expose at least a portion of the second conductors 530 for further electrical connection.

Referring to FIG. 3C and FIG. 3D, after forming the encapsulant 220, the second conductive pattern 540 may be formed on the second conductors 530 and the second back surface 514 of the second semiconductor chip 510. For example, the second passivation layer P2′ having a plurality of openings P2a′ may be formed on the encapsulant 220 and the second semiconductor chip 510 and the openings P2a′ exposes at least a portion of the second conductors 530. Next, the second conductive pattern 540 may be formed in the openings P2a′ of the second passivation layer P2′. In some embodiments, the forming process of the second passivation layer P2′ and the second conductive pattern 540 may be performed multiple times to obtain the multi-layered circuitry as required by the circuit design. The topmost second passivation layer P2′ may have openings P2a′ exposing at least the portion of the topmost second conductive pattern 540 for further electrical connection. After forming the second conductive pattern 540, the subsequent manufacturing processes may be similar with the embodiments described in FIG. 1H to FIG. 1J, and the detailed descriptions are omitted. After performing the singulation process and removing the temporary carrier 50, the manufacturing process of a semiconductor package 200 is substantially completed as shown in FIG. 3D.

Based on the above, the cover layer covering the first active surface of the first semiconductor chip may protect the sensing area on the first active surface from being damage in the subsequent assembling processes. In addition, the distance between the cover layer and the sensing area is minimized, thereby achieving improved sensing capabilities of the semiconductor package. The second active surface of the second semiconductor chip faces towards the first back surface of the first semiconductor chip. In addition, the first conductive pattern and the first conductors are electrically connected between the first semiconductor chip and the second semiconductor chip. As a result, the semiconductor package may keep a short electrical conduction path from the first semiconductor chip to the second semiconductor chip in order to reduce signal propagation, lower capacitance, and achieve better circuit performance. Furthermore, the third semiconductor chip having the conductive connectors faces towards the second back surface of the second semiconductor chip and electrically connects to the first semiconductor chip and the second semiconductor chip through the first conductive pattern and the second conductive pattern. As such, the manufacturing method of the semiconductor package integrating the first semiconductor chip, the second semiconductor chip and the third semiconductor chip may achieve better operating performances and greater manufacturability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor package, comprising:
a plurality of first semiconductor chips, each of the first semiconductor chips comprising a first active surface, a sensing area on the first active surface, a first back surface opposite to the first active surface and a plurality of through holes extending form the first back surface towards the first active surface, wherein one of the first semiconductor chips collects wavelengths of light different from wavelengths of light collected by another of the first semiconductor chips, and spectral responsivities of the first semiconductor chips are complementary to one another;
a plurality of first conductors disposed in the through holes of the first semiconductor chips and electrically connected to the first semiconductor chips;
a first conductive pattern disposed on the first back surfaces of the first semiconductor chips and electrically connected to the first conductors;
a second semiconductor chip disposed on the first conductive pattern and comprising a second active surface facing towards the first back surfaces of the first semiconductor chips, wherein the second semiconductor chip is electrically connected to the first semiconductor chips through the first conductive pattern; and
an encapsulant disposed on the first conductive pattern and laterally encapsulating the second semiconductor chip.

2. The semiconductor package according to claim 1, further comprising:
an encapsulating layer laterally encapsulating the first semiconductor chips, wherein the second semiconductor chip and the encapsulant are disposed on the first semiconductor chips and the encapsulating layer.

3. The semiconductor package according to claim 1, further comprising:
a plurality of conductive features disposed between the first semiconductor chips and the second semiconductor chip and encapsulated by the encapsulant, wherein the second semiconductor chip is electrically connected to the first semiconductor chips through the first conductors, the first conductive pattern and the conductive features.

4. The semiconductor package according to claim 1, further comprising:
a plurality of second conductors disposed on the first conductive pattern and surrounding the second semiconductor chip, wherein the second conductors are electrically connected to the first conductors through the first conductive pattern.

5. The semiconductor package according to claim 4, wherein the encapsulant comprises a plurality of through holes surrounding the second semiconductor chip, the second conductors are disposed in the through holes of the encapsulant.

6. The semiconductor package according to claim 4, further comprising:
a second conductive pattern disposed on a second back surface of the second semiconductor chip opposite to the second active surface, wherein the second conductive pattern is electrically connected to the second conductors.

7. The semiconductor package according to claim 6, further comprising:
a third semiconductor chip disposed on the second conductive pattern, wherein the third semiconductor chip is electrically connected to the first semiconductor chips and the second semiconductor chip.

8. The semiconductor package according to claim 6, further comprising:
a plurality of conductive terminals disposed on the second conductive pattern wherein the conductive terminals are electrically connected to the first semiconductor chips and the second semiconductor chip.

9. The semiconductor package according to claim 1, further comprising:
a cover layer covering the sensing areas of the first semiconductor chips.

10. The semiconductor package according to claim 1, wherein each of the first conductors comprises an insulating layer disposed on an inner sidewall of the through holes, a barrier layer disposed on the insulating layer, a seed layer conformally disposed on the barrier layer, and a conductive layer conformally disposed on the seed layer.

11. The semiconductor package according to claim 1, wherein each of the first semiconductor chips comprises a plurality of first conductive pads on the first active surface surrounding the sensing area, the through holes expose the first conductive pads, and the first conductors are electrically connected to the first conductive pads.

12. A manufacturing method of a semiconductor package, comprising:
providing a plurality of first semiconductor chips, wherein each of the first semiconductor chips comprises a first active surface, a sensing area on the first active surface, a first back surface opposite to the first active surface and a plurality of through holes extending from the first back surface towards the first active surface, and one of the first semiconductor chips collects wavelengths of light different from wavelengths of light collected by another of the first semiconductor chips, and spectral responsivities of the first semiconductor chips are complementary to one another;
forming a plurality of first conductors in the through holes of the first semiconductor chips;
forming a first conductive pattern on the first back surface of each of the first semiconductor chips to electrically connect the first conductors;
disposing a second semiconductor chip on the first conductive pattern, wherein the second semiconductor chip comprises a second active surface facing towards the first back surface of each of the first semiconductor chips, and the second semiconductor chip is electrically connected to the first semiconductor chips; and
forming an encapsulant on the first conductive pattern to laterally encapsulate the second semiconductor chip.

13. The manufacturing method according to claim 12, further comprising:
forming an encapsulating layer to laterally encapsulate the first semiconductor chips before forming the first conductors.

14. The manufacturing method according to claim 12, further comprising:
forming a plurality of conductive features on the first conductive pattern before disposing the second semiconductor chip, wherein after disposing the second semiconductor chip, the second semiconductor chip is electrically connected to the first semiconductor chips through the first conductors, the first conductive pattern and the conductive features.

15. The manufacturing method according to claim 12, further comprising:
forming a plurality of second conductors on the first conductive pattern to electrically connect the first conductors and the first semiconductor chips, wherein after forming the encapsulant, the second conductors are laterally encapsulated by the encapsulant.

16. The manufacturing method according to claim 15, further comprising:
forming a second conductive pattern on a second back surface of the second semiconductor chip opposite to the second active surface, wherein after forming the second conductive pattern, the second semiconductor chip is electrically connected to the second conductive pattern through the second conductors.

17. The manufacturing method according to claim 16, further comprising:
disposing a third semiconductor chip on the second conductive pattern, wherein the third semiconductor chip is electrically connected to the first semiconductor chips and the second semiconductor chip.

18. The manufacturing method according to claim 16, further comprising:
forming a plurality of conductive terminals on the second conductive pattern wherein the conductive terminals are electrically connected to the first semiconductor chips and the second semiconductor chip.

19. The manufacturing method according to claim 12, wherein providing the first semiconductor chips comprises:
providing a temporary carrier;
forming a cover layer on the temporary carrier; and
disposing the first semiconductor chips on the cover layer, wherein the first active surface of each of the first semiconductor chips faces towards the cover layer.

20. The manufacturing method according to claim 12, wherein forming the first conductors in the through holes of the first semiconductor chips comprises:
forming an insulating layer on an inner sidewall of each of the through holes;
forming a barrier layer on the insulating layer;
conformally forming a seed layer on the barrier layer; and
conformally forming a conductive layer on the seed layer.
